(19) United States
(12) Patent Application Publication
(10) Pub. No.: US 2008/0160905 A1
(43) Pub. Date: Jul. 3, 2008

(54) EXHAUST UNIT, EXHAUSTING METHOD, AND SEMICONDUCTOR MANUFACTURING FACILITY WITH THE EXHAUST UNIT

(76) Inventors: Moon-Jeong Kim, Gyeonggi-do (KR); Kang-Ho Ahn, Gyeonggi-do (KR); Suck-Hoon Kang, Gyeonggi-do (KR); Jae-Young Lee, Seoul (KR); Jai-Heung Choi, Gyeonggi-do (KR); Jung-Sung Hwang, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/968,039

(22) Filed: Dec. 31, 2007

(30) Foreign Application Priority Data
Jan. 3, 2007 (KR) 10-2007-00740

(51) Int. Cl. F24F 7/00; H01L 21/02; F24F 13/10

(52) U.S. Cl. 454/340; 454/49; 454/187

(57) ABSTRACT

Provided is an exhaust unit capable of preventing large pressure fluctuations within a process chamber due to atmospheric pressure changes. The exhaust unit includes a main exhaust duct and a supplemental exhaust duct that acts as a partial bypass. A flap is located at a downstream opening between the main exhaust duct and supplemental exhaust duct and controls the amount of bypassed gas flowing from the supplemental exhaust duct to the main exhaust duct. First and second plates of the flap are pivotally coupled to the main exhaust duct adjacent the downstream opening, the first plate colliding with gas flowing through the main exhaust duct and the second plate partially blocking bypassed gas flowing back into the main exhaust duct from the supplemental exhaust duct. When gas is exhausted through the main exhaust line and the supplemental exhaust duct, the flap passively controls the amount by which the supplemental exhaust duct is opened through fluctuations in atmospheric pressure.

### CROSS-REFERENCE TO RELATED APPLICATIONS

This U.S. non-provisional patent application claims priority under 35 U.S.C. §119 of Korean Patent Application No. 10-2007-00740, filed on Jan. 3, 2007, the entire contents of which are hereby incorporated by reference.

### BACKGROUND OF THE INVENTION

The present invention disclosed herein relates to a semiconductor manufacturing facility, and more particularly, to an exhaust unit and an exhausting method for exhausting gas from a process chamber to lower the pressure within the process chamber.

Typically, a semiconductor manufacturing facility has a plurality of process chambers within a clean room and exhaust units that control the pressures within the process chambers. Each process chamber is connected to a branch duct for exhausting gas from therein, and the respective branch ducts are connected to a main duct. The main duct is formed of a primary duct with a fan installed, and a secondary duct connected to the branch ducts. Typically, the fan is controlled to adjust the volume of exhausted gas according to the atmospheric pressure, and the pressure within the process chamber is affected by the volume of gas exhausted by the fan.

During processing, the pressure inside the process chamber should be maintained at a low pressure, and any variation in pressure should occur within a minimal range. However, when pressure variation over a wide range occurs during use of typical exhaust units as those described above, the pressure within the process chamber also fluctuates over a wide range, leading to manufacturing defects. FIG. 1 is a graph showing variations in the thickness of an oxide layer formed on a wafer according to fluctuations in atmospheric pressure during a diffusion process. As shown in FIG. 1, the fluctuation range of atmospheric pressure directly affects the thickness of an oxide layer formed on a wafer within a process chamber, so that when the atmospheric pressure fluctuates widely, uniformity in the thickness of an oxide layer over a wafer deteriorate.

Also, when process chambers are added to or removed from the clean room, the total volume of gas that is exhausted through the main duct is altered, necessitating manual adjustment of the opening ratio of each damper provided respectively in the secondary ducts. This task consumes much time and manpower.

Accordingly, the need exists for exhaust units and methods that better regulate pressure fluctuations within process chambers.

### SUMMARY OF THE INVENTION

The present invention provides an exhaust unit and exhausting method capable of efficiently controlling pressure within a process chamber, and a semiconductor manufacturing facility with the exhaust unit.

The present invention also provides an exhaust unit and exhausting method capable of preventing wide pressure fluctuation within a process chamber due to external influences, and a semiconductor manufacturing facility with the exhaust unit.

Provisions of the present invention are not limited hereto, and may include other provisions that are not described, which will become clear to those skilled in the art from the description provided below.

Embodiments of the present invention provide exhaust units used to regulate pressure in a process chamber, the exhaust units including: a main exhaust duct connected to the process chamber, and including at least one of a first opening and a second opening defined in a sidewall thereof; and at least one supplementary exhaust duct with one end connected to the first opening and the other end connected to the second opening, to allow a portion of gas flowing through the main exhaust duct to diverge from the main exhaust duct through the first opening, and re-enter the main exhaust duct through the second opening. A regulating member allowing regulating of an opening ratio of the second opening is provided in the exhaust unit.

In some embodiments, the regulating member may include a flap altering the opening ratio of the second opening through colliding with a volume of gas flowing through the main exhaust duct, and the flap may decrease the opening ratio of the second opening as the volume of gas that the flap collides with in the main exhaust duct increases.

In other embodiments, one end of the flap may be installed near an end of the second opening that is closer to the first opening, and the other end of the flap may be a free end.

In still other embodiments, the flap may include a first plate and a second plate bending and extending from the first plate. The regulating member may further include a hinge coupling an intersecting axis, at which the second plate bends and extends from the first plate, to the main exhaust duct or the supplementary exhaust duct.

In even other embodiments, the regulating member may further include: a bearing fixed to the main exhaust duct or the supplementary exhaust duct; and a rotating axis rotatably inserted in the bearing to fix the first plate and the second plate.

In yet further embodiments, the regulating member may further include a connecting member of a rubber material, for fixing an intersecting axis, at which the second plate bends and extends from the first plate, to the main exhaust duct or the supplementary exhaust duct.

In yet other embodiments, the exhaust unit may further include a damper disposed between the first opening and the second opening, to regulate the opening ratio of the main exhaust duct.

In further embodiments, the main exhaust duct may have a rectangular cross section cut across a lengthwise direction thereof. The main exhaust duct may have opposing sidewalls, and the supplementary exhaust duct may be provided respectively on each of the sidewalls. The supplementary exhaust duct may be formed in a shape of a container open at one side, and the open side may communicate with the first and second openings.

In still further embodiments, the regulating member may include: a flap rotating to regulate an opening ratio of the second opening; a driver rotating the flap; an airflow measurer measuring a volume of gas flowing through the main exhaust duct or the supplementary exhaust duct; and a controller controlling the driver, based on a measured value received from the airflow measurer.

In other embodiments of the present invention, semiconductor manufacturing facilities include: a clean room; a plurality of process chambers arranged within the clean room, to perform a semiconductor process; and an exhaust unit regulating a pressure of the process chambers, wherein the exhaust unit includes: an integration duct having a pressure controlling member regulating an exhaust pressure, according to a fluctuation of an atmospheric pressure; and separation ducts diverging from the integration duct and coupled to the processing chambers. The integration duct may be embodied in various configurations in the above-described exhaust unit.

In still other embodiments, the integration duct may further have a primary duct with the pressure controlling member installed therein, and a secondary duct diverging from the primary duct, having the separation ducts connected thereto, and having the main exhaust duct, the supplementary exhaust duct, and the regulating member.

In still other embodiments of the present invention, methods for exhausting gas from a process chamber are provided. The methods include simultaneously exhausting gas from within a process chamber through a main exhaust duct and a supplementary exhaust duct, based on a fluctuation of external pressure, the supplementary exhaust duct being a chamber into which the gas diverges from and then re-enters the main exhaust duct, wherein an opening ratio of the supplementary exhaust duct is changed according to the fluctuation of the external pressure, to reduce a range of pressure fluctuation of an internal pressure of the process chamber based on the fluctuation of the external pressure.

In still other embodiments, the changing of the opening ratio of the supplementary exhaust duct may be performed through changing an angle between an opening provided for allowing the gas flowing through the supplementary exhaust duct to enter the main exhaust duct, and a flap rotatably installed in an integration exhaust duct.

In yet other embodiments, the flap may be rotated through a change in a volume of gas colliding with the flap as the gas flows through the main exhaust duct.

In further embodiments, the opening ratio of the supplementary exhaust duct may increase when the external pressure increases. The opening ratio of the supplementary exhaust duct may decrease when the external pressure decreases.

In still further embodiments, the flap may be rotated by a driver, and a flow volume within the supplementary exhaust duct or the main exhaust duct may be measured and a rotated angle of the flap may be changed according to a value of the measurement.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a graph showing variations in the thickness of an oxide layer formed on a wafer according to fluctuations in atmospheric pressure during a diffusion process;

FIG. 2 is a plan view of a semiconductor manufacturing facility according to one embodiment of the present invention;

FIG. 3 is a perspective view of a secondary duct in FIG. 2;

FIG. 4 is an exploded perspective view of the secondary duct in FIG. 3;

FIG. 5 is a cross-sectional view of the secondary duct in FIG. 3;

FIG. 6 is an exploded perspective view of the secondary duct in FIG. 3 with two identically-shaped supplementary exhaust ducts;

FIGS. 7 through 9 are perspective views of various embodiments of flaps that are installed on main exhaust ducts;

FIGS. 10 and 11 are diagrams respectively showing a reduction and an elevation in atmospheric pressure in a typically configured exhaust unit with only a main exhaust duct, and the change in flow quantity within the duct when the exhaust unit in FIG. 3 is used;

FIGS. 12(a) and (b) are graphs comparing the fluctuation of pressure in a process chamber over time when a typically configured exhaust unit is used, with the fluctuation of pressure in a process chamber over time when the exhaust unit in FIG. 3 is used;

FIG. 13 is a cross-sectional view of a secondary duct with regulating members installed therein according to another embodiment;

FIG. 14 is a partial perspective view showing the regulating member in FIG. 13;

FIG. 15 and FIG. 16 are respectively a perspective and cross-sectional view of a secondary duct with regulating members installed according to another embodiment; and

FIG. 17 is a schematic cross-sectional view of a semiconductor manufacturing facility according to another embodiment of the present invention.

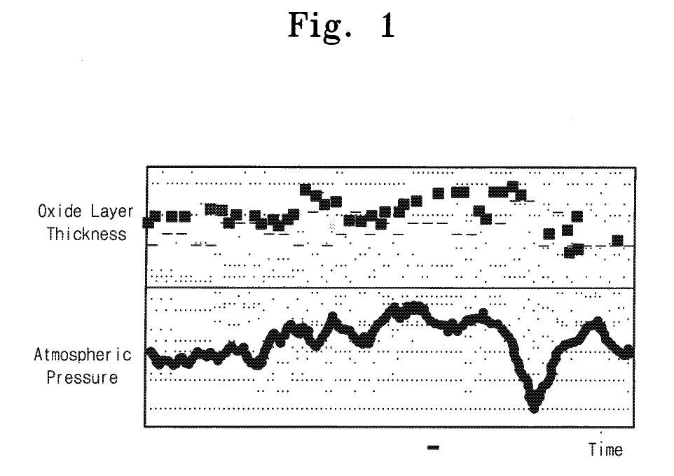

### DETAILED DESCRIPTION OF PREFERRED EMBODIMENTS

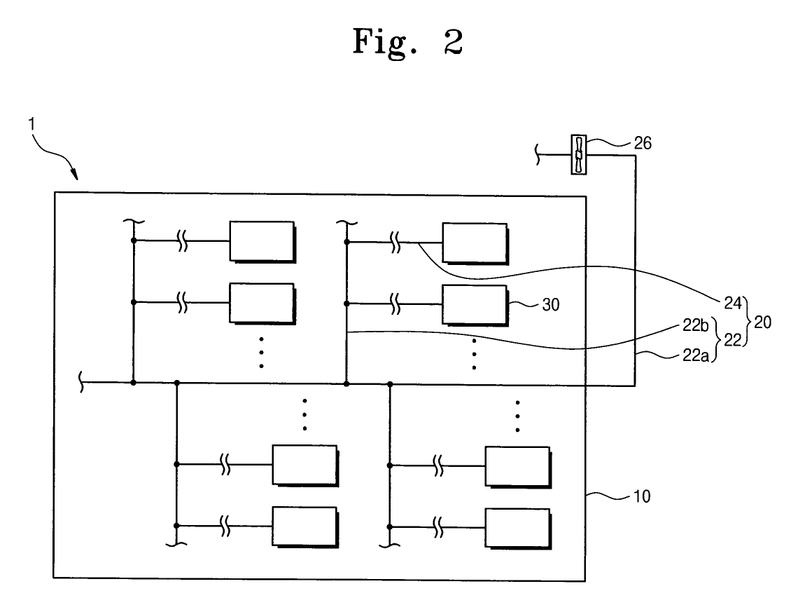

Preferred embodiments of the present invention will be described below in more detail with reference to FIGS. 2 through 17. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Thus, elements in the drawings are exaggerated for clarity of illustration.

Hereinafter, an exemplary embodiment of a structure of an exhaust unit 20 provided on a semiconductor manufacturing facility 1 according to the present invention will be described. The technical scope of the present invention, however, is not limited hereto, and the exhaust unit 20 may be employed in various other applications in which exhaust volume fluctuates due to external influences.

FIG. 2 is a plan view of a semiconductor manufacturing facility 1 according to one embodiment of the present invention. Referring to FIG. 2, a semiconductor manufacturing facility 1 includes a clean room 10, an exhaust unit 20, and a plurality of process chambers 30. The clean room 10 provides a space maintained at a high level of cleanliness compared to the 1external environment. A plurality of different types of filters (not shown) is installed in the clean room 10 to remove impurities from air entering the clean room 10.

A plurality of process chambers 30 is provided within the clean room 10. The process chambers 30 are configured to perform predetermined processes on semiconductor wafers, flat panel displays, etc. The process chambers 30 may be configured to perform deposition, photo processing, etching, polishing, and inspection. The process chambers 30 are provided in groups. Process chambers 30 in the same group may be configured to perform the same processes, and those in different groups may be configured to perform other processes.

Each process chamber 30 maintains a process pressure in a preset range during a process. The exhaust unit 20 maintains the process pressure within the process chamber 30, and exhausts residual material inside the process chamber 30 to the outside. The exhaust unit 20 has an integration duct 22 and a separation duct 24. A separation duct 24 is directly attached to each process chamber 30. The integration duct 22 includes a primary duct 22a and a secondary duct 22b. The secondary duct 22b branches from the primary duct 22a, and the separation duct 24 branches in singularity or plurality from each secondary duct 22b. Therefore, gas exhausted through a plurality of individual ducts 24 is integrated and exhausted into the secondary duct 22b to which each separation duct 24 is connected, and the gas exhausted through the secondary ducts 22b is integrated and exhausted into the primary ducts 22a and exhausted to the outside. Process chambers 30 connected to separation ducts 24 that branch from the same secondary duct 22b may be process chambers 30 performing the same process.

The integration duct 22 is sectionally rectangular overall (when cut perpendicularly to its length), and the separation duct 24 is sectionally circular overall (when cut perpendicularly to its length). The cross sectional area of the secondary duct 22b, which combines and exhausts gas exhausted from the plurality of separation ducts 24, is sufficiently large with respect to the aggregate cross sectional area of the separation ducts 24, and the cross sectional area of the primary duct 22a, which combines and exhausts gas exhausted from the plurality of secondary ducts 22b, is sufficiently large with respect to the aggregate cross sectional area of the secondary ducts 22b.

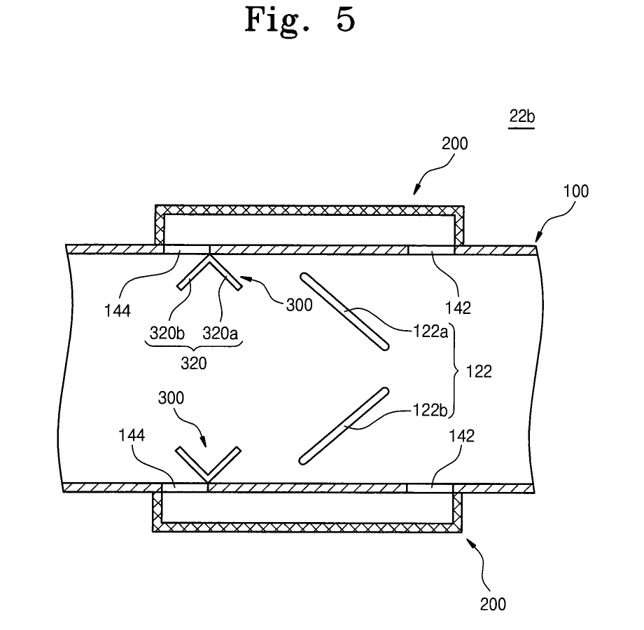

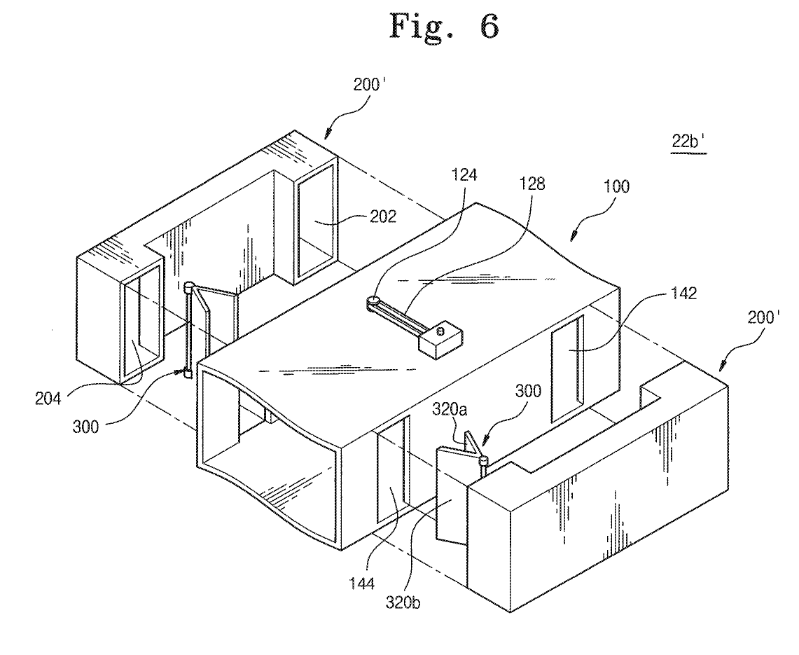

A damper 122 (see, e.g., FIG. 5) is provided in each of the secondary ducts 22b to adjust the opening ratio of the duct. In one embodiment, the damper 122 has two vanes 122a and 122b disposed linearly within the secondary duct 22b. Each vane 122a and 122b is shaped as a rectangular plate, and is rotatably mounted at the middle thereof. The respective central shafts about which the vanes rotate may be linked to one another through a belt 128 and pulley 124 assembly (see, e.g., FIG. 6). When the vanes 122a and 122b are disposed in a straight line, the opening ratio of the secondary duct 22b is lowest. As the vanes 122a and 122b both rotate, the opening ratio of the secondary duct 22b gradually increases until it reaches its highest point when the vanes 122a and 122b become disposed perpendicularly to the long axis of the secondary duct—that is, where the vanes are most constricting to the flow of gases through the duct. The rotation of the vanes 122a and 122b may be manually performed by an operator, and the opening ratio of the secondary duct 22b is fixed during the rotation by means of the damper 122. Alternately, the rotation of the vanes 122a and 122b may be performed automatically, and the opening ratio of the secondary duct 22b is fixed during the rotation by means of the damper 122.

A fan 26 (FIG. 2) or other pressure regulating member 300 (FIG. 5) is installed on the primary duct 22a. The fan 26 controls the amount of gas being exhausted through the primary duct 22a by maintaining a pressure difference within the separation duct 24 and the atmospheric pressure within a certain range. Accordingly, when the atmospheric pressure increases, the volume of gas exhausted through the integration duct 22 decreases, and when the atmospheric pressure decreases, the volume of gas exhausted through the integration duct 22 increases. The pressure within the process chamber 30 changes according to the fluctuation of the atmospheric pressure, and the pressure inside the process chamber 30 can deviate from a preset pressure range through fluctuation of the atmospheric pressure, depending on the type of process being performed in the process chamber 30. In this case, a flow adjusting valve (not shown) is installed to adjust the opening ratio of the separation duct 24, so that the pressure inside the process chamber 30 can be maintained within preset pressure parameters.

Manufacturing defects occur when pressure adjusting of the process chamber 30 (to offset the effects of atmospheric pressure fluctuation) is not performed quickly enough so that the pressure in the process chamber 30 deviates from the preset parameters. Also, even if the pressure within the process chamber 30 is within the preset parameters, wide fluctuations of pressure within the process chamber 30 during the performing of a process reduces process efficiency. The exhaust unit 20 according to the present embodiment is structured to reduce the effects that atmospheric pressure fluctuation has on pressure changes within the process chamber 30. Also, the exhaust unit 20 according to the present embodiment is configured to prevent the pressure within the process chamber 30 from deviating from the preset parameters by a fast response to a change in atmospheric pressure.

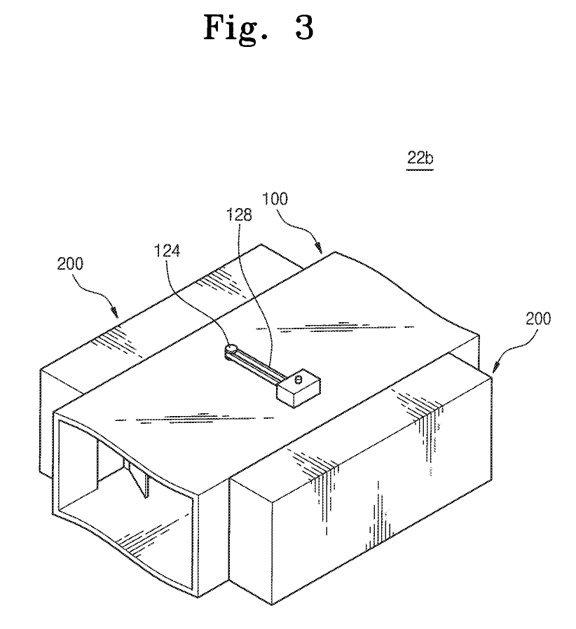

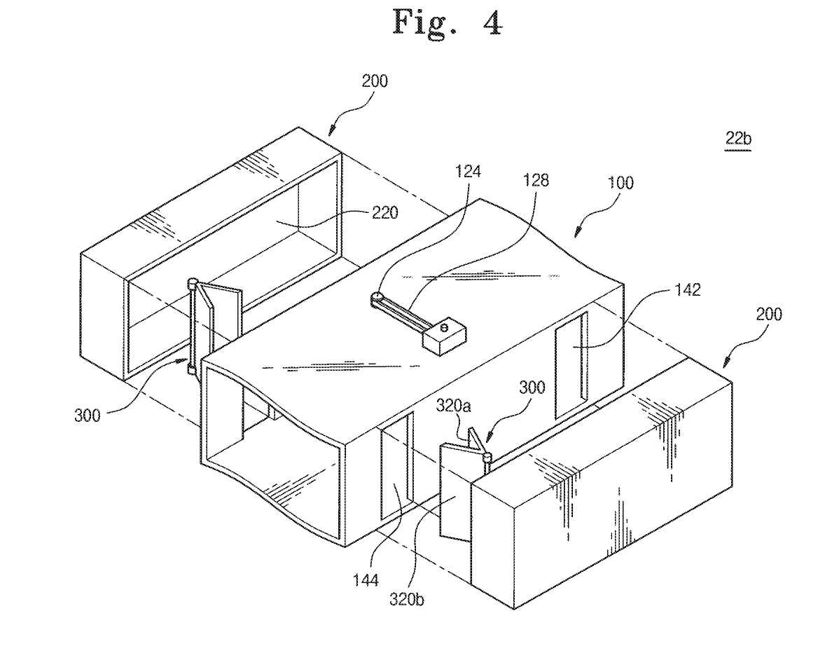

FIGS. 3 through 5 are exemplary embodiments of a secondary duct 22b. FIG. 3 is a perspective view of a secondary duct 22b in FIG. 2, FIG. 4 is an exploded perspective view of the secondary duct in FIG. 3, and FIG. 5 is a cross-sectional view of the secondary duct in FIG. 3. Referring to FIGS. 3 through 5, the secondary duct 22b has a main exhaust duct 100, a supplementary exhaust duct 200, and a regulating member 300. The main exhaust duct 100 branches from the primary duct 22a. The supplementary exhaust duct 200 is connected to communicate at both ends with the main exhaust duct 100. One end of the supplementary exhaust duct 200 is connected to the main exhaust duct 100 such that a portion of gas being exhausted through the main exhaust duct 100 can enter the supplementary exhaust duct 200, and the other end of the supplementary exhaust duct 200 is connected to the main exhaust duct 100 to allow the gas flowing through the supplementary exhaust duct 200 to flow back into the main exhaust duct 100. That is, the supplementary exhaust duct 200 is provided as a bypass line to the main exhaust duct 100, allowing a portion of the gas flowing through the main exhaust duct 100 to flow through the supplementary exhaust duct 200 and then re-enter the main exhaust duct 100.

As described above, the main exhaust duct 100 has a rectangular cross-sectional shape, with an area that is uniform throughout its length, through which gas flows. Referring to FIG. 4, the supplementary exhaust duct 200 is provided as a hexahedral container with one side open. The supplementary exhaust duct 200 is coupled to the main exhaust duct 100 with the open side facing a side of the main exhaust duct 100. A first opening 142 and a second opening 144 are defined in the main exhaust duct 100, and the supplementary exhaust duct 200 has a length that enables the open side to face the first opening 142 and the second opening 144 at respective ends of the open side. The first opening 142 functions as an inlet for gas flowing through the main exhaust duct 100 to flow into the supplementary exhaust duct 200, and the second opening 144 serves as an outlet for gas flowing through the supplementary exhaust duct 200 to flow back into the main exhaust duct 100. The supplementary exhaust duct 200 and the main exhaust duct 100 may be connected by fastening means such as screws (not shown), and a sealer (not shown) may be used to prevent the occurrence of gaps between the fastening means through which gas may leak.

To allow sufficient volumes of gas to enter the supplementary exhaust duct 200 from the main exhaust duct 100, the heights of the supplementary exhaust duct 200 and the main exhaust duct 100 may be the same or similar. Also, the heights of the first opening 142 and the second opening 144 defined in the main exhaust duct 100 may be the same as the height of the main exhaust duct 100, and the widths of the first opening 142 and the second opening 144 are the same.

The supplementary exhaust duct 200 is connected to the main exhaust duct 100 at a position between the point where the main exhaust duct 100 branches from the primary duct 22a and a point where the separation duct 24 primarily branches from the secondary duct 22b. The above-described damper 122 installed on the secondary duct 22b is coupled to the main exhaust duct 100 at a position between the first opening 142 and the second opening 144. The supplementary exhaust duct 200 is provided respectively in opposition at either side of the main exhaust duct 100. Selectively, the supplementary exhaust duct 200 may be provided respectively on three sides of the main exhaust duct 100.

FIG. 6 is an exploded perspective view of the secondary duct 22b′ in FIG. 3 with two identically shaped supplementary exhaust ducts 200′. Referring to FIG. 6, the supplementary exhaust duct 200′ is provided as a tube formed roughly in a C-shape with open front and rear ends. The supplementary exhaust duct 200′ is coupled to the main exhaust duct 100, such that the front end communicates with the first opening 142, and the rear end communicates with the second opening 144.

A regulating member is 300 installed on the secondary duct 22b to regulate the opening ratio of the second opening 144. Here, the opening ratio of the second opening 144 is controlled by adjusting the volume of gas flowing through the second opening 144. This involves not only providing a plate in the area of the second opening 144 to directly alter the area of the second opening 144, but also regulating the angle between the plate and the second opening 144 so that the degree of interference of the plate with the flow of gas can be changed.

When the flow volume through the secondary duct 22b changes due to changes in the external environment, such as fluctuations in atmospheric pressure, the regulating member 300 regulates the amount of gas that can flow through the supplementary exhaust duct 200, in order to reduce the pressure fluctuation range. For example, when atmospheric pressure becomes high, the pressure within the process chamber 30 is increased, and the flow of gas through the secondary duct 22b is decreased. In this case, the regulating member 300 increases the opening ratio of the secondary duct 144 so that a larger volume of gas can flow through the supplementary exhaust duct 200, in order to reduce the range of flow reduction through the secondary duct 22b. Thus, the pressure within the process chamber 30 increases within a smaller range. Conversely, when atmospheric pressure becomes low, the pressure within the process chamber 30 is reduced, and the flow volume through the secondary duct 22b is increased. Here, the regulating member 300 decreases the opening ratio of the secondary duct 144 so that a smaller volume of gas can flow through the supplementary exhaust duct 200, in order to reduce the range of flow reduction through the secondary duct 22b. Thus, the pressure range within the process chamber 30 is prevented from broadening.

According to one embodiment of the present invention, the regulating member 300 is configured to be capable of regulating the opening ratio of the secondary duct 144 according to fluctuations in atmospheric pressure without a separate motive force. Referring again to FIGS. 4 and 5, the regulating member 300 has a flap 320 installed rotatably within the main exhaust duct 100. The flap 320 includes a first plate 320a and a second plate 320b. The first plate 320a and the second plate 320b are respectively shaped as rectangular plates. The first plate 320a extends at an angle from an end of the second plate 320b. The first plate 320a and the second plate 320b may be disposed to be approximately perpendicular to each other. Selectively, the first plate 320a and the second plate 320b may collectively form an acute angle. The second plate 320b is formed to be approximately the same in size and shape to the second opening 144. However, the width of the second plate 320b may be formed to be slightly greater than the width of the second opening 144. The flap 320 is fixed and installed to the main exhaust duct 100 at the side of the second opening 144 closer to the first opening 142.

The second plate 320b is disposed between the first plate 320a and the second opening 144. The first plate 320a functions mainly to collide with gas flowing through the main exhaust duct 100, and the second plate 320b rotates together with the first plate 320a, and regulates the opening ratio of the second opening 144. The flap 320 rotates toward the second opening 144 when the flow volume through the main exhaust duct 100 increases, and rotates away from the second opening 144 when the flow volume through the main exhaust duct 100 decreases. The rotation of the flap 320 may be realized automatically through collision of the first plate 320a with gas flowing through the main exhaust duct 100 and collision of the second plate 320b with gas flowing through the supplementary exhaust duct 200.

The flap 320 has been described above to include the first plate 320a and the second plate 320b. However, the flap 320 may include only one plate.

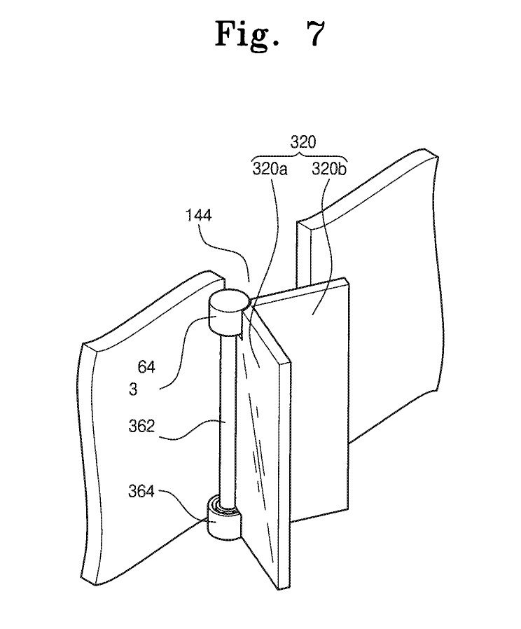

FIGS. 7 through 9 are perspective views of various embodiments of flaps 320 that are 1installed on main exhaust ducts 100. Referring to FIG. 7, a bearing 364 is fixedly installed at the top and bottom end of the main exhaust duct 100, the portion connecting the first plate 320a and the second plate 320b is fixed to a rotating shaft, and both ends of the rotating shaft 362 are inserted into the bearings 364, thus enabling the flap 320 to rotate smoothly.

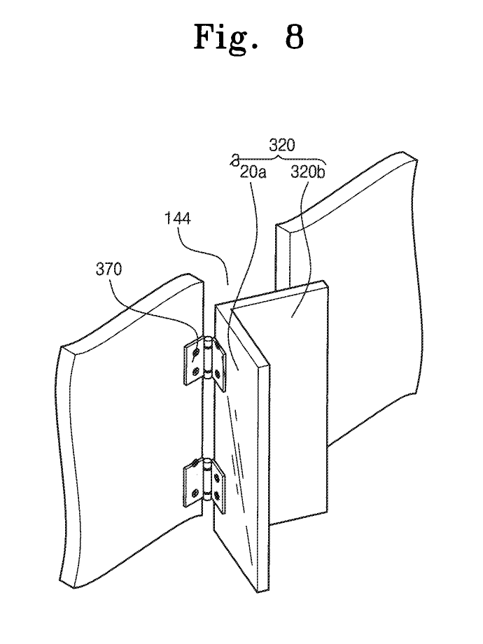

Referring to FIG. 8, a hinge 370 (or pair of such hinges 270, as shown) may be installed at the intersecting axis of the first plate 320a and the second plate 320b, and the flap 320 may be coupled through the hinge 370 to the main exhaust duct 100.

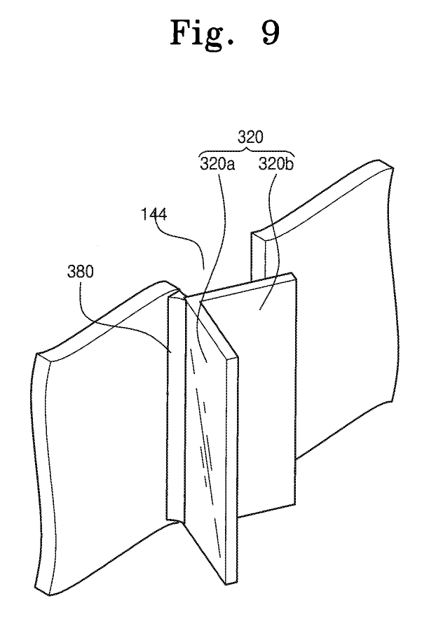

Referring to FIG. 9, the flap 320 may be fixed to the main exhaust duct 100 by means of a resiliently flexible (e.g. rubber) connecting member 380. Here, the connecting member 380 is coupled to the intersecting axis of the first plate 320a and the second plate 320b. The connecting member 380 may be fixed to the flap 320 and main exhaust duct 100 with an adhesive.

The flap 320 in the above description is fixedly installed to the main exhaust duct 100. However, the flap 320 may alternately be fixedly installed at another location. Also, while the first plate 320a and second plate 320b of the flap 320 have been described above as being respectively rectangular, the first plate 320a and the second plate 320b may be embodied in various alternate shapes. The first plate 320a and the second plate 320b may be the same in terms of size, shape, material, etc. The flap 320 may be coupled to the main exhaust duct 100 through an elastic member (not shown) biased in the direction in which the opening ratio increases.

The secondary duct 22b has been described above as including the main exhaust duct 100, the supplementary exhaust duct 200, and the flap 320. However, the above configuration may be applied instead to the primary duct 22a.

The flap 320 may be made of various materials. For example, polyvinyl chloride with high acid corrosion resistance or stainless steel with organic corrosion resistance may be used as a material for the flap 320. Also, galvanized steel with high thermal endurance may be used as material for the flap 320. The material for the flap 320 may be selected based on what ingredients are inherent in gas exhausted from the process chamber 30 connected to each secondary duct 22b, or the temperature of the exhausted gas. For example, a flap 320 provided in a secondary duct 22b (from a plurality of secondary ducts 22b) through which mostly acidic gas is exhausted may be made of a polyvinyl chloride material, a flap 320 provided in a secondary duct 22b through which mostly gas with organic content is exhausted may be made of a stainless steel material, and a flap 320 provided in a secondary duct 22b through which mostly high temperature gas is exhausted may be made of a galvanized steel material.

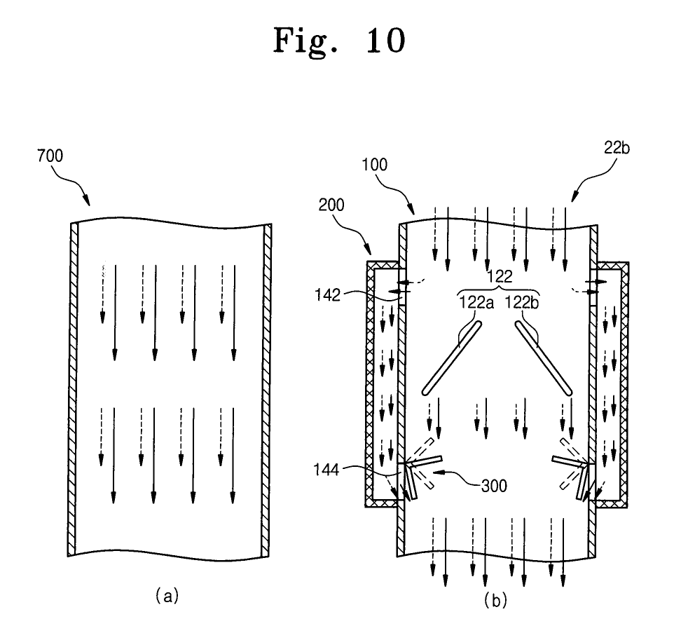

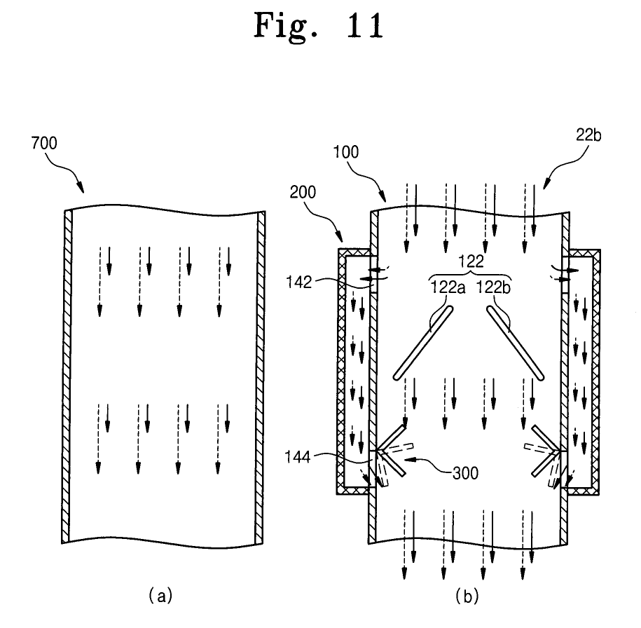

FIGS. 10 and 11 are diagrams respectively showing a reduction and an elevation in atmospheric pressure in a typically configured exhaust unit with only a main exhaust duct 100, and the change in flow quantity within the duct when the exhaust unit 20 in FIG. 3 is used. Referring to FIGS. 10 and 11, the lengths of the arrows represent the volume (or speed) of gas being exhausted through the ducts. The dotted lines represent the volume (or speed) of gas being exhausted through the ducts prior to a change in atmospheric pressure, and the solid lines represent the volume (or speed) of gas being exhausted through the ducts following a change in atmospheric pressure to a high pressure or a low pressure, respectively.

Referring to FIG. 10, when a typically configured exhaust unit is used, when atmospheric pressure drops to a low pressure, the rotating speed of the fan 26 is increased. Because there is no change to the sectional area of the duct 700 through which gas flows, the flow volume of gas increases greatly. On the other hand, when an exhaust unit 20 according to embodiments of the present invention is used, when atmospheric pressure drops to a low pressure, the flaps 320 rotate in directions toward the secondary openings 144, thus reducing the opening ratios of the second openings 144. Therefore, even when the rotation speed of the fan 26 increases, because the sectional area of the secondary duct 22b through which the gas flows is reduced, the increase in gas flow through the secondary duct 22b is comparatively small.

Conversely, when referring to FIG. 11, when a typically configured exhaust unit is used, when atmospheric pressure rises to a high pressure, the rotating speed of the fan 26 is decreased. Because there is no change to the sectional area of the duct 700 through which gas flows, the flow volume of gas through the duct 700 decreases. On the other hand, when an exhaust unit 20 according to embodiments of the present invention is used, when atmospheric pressure rises to a high pressure, the flaps 320 rotate in directions away from the secondary openings 144, thus increasing the opening ratios of the second openings 144. Therefore, even when the rotation speed of the fan 26 decreases, because the sectional area of the secondary duct 22b through which the gas flows is enlarged, the decrease in gas flow through the secondary duct 22b is comparatively small.

Accordingly, when an exhaust unit 20 according to embodiments of the present invention is used, the fluctuation range of the volume of gas flow according to changes in atmospheric pressure is smaller than when a typical exhaust unit is used, so that the pressure fluctuation range within the process chamber 30 is smaller, resulting in more efficient processing within the process chamber 30.

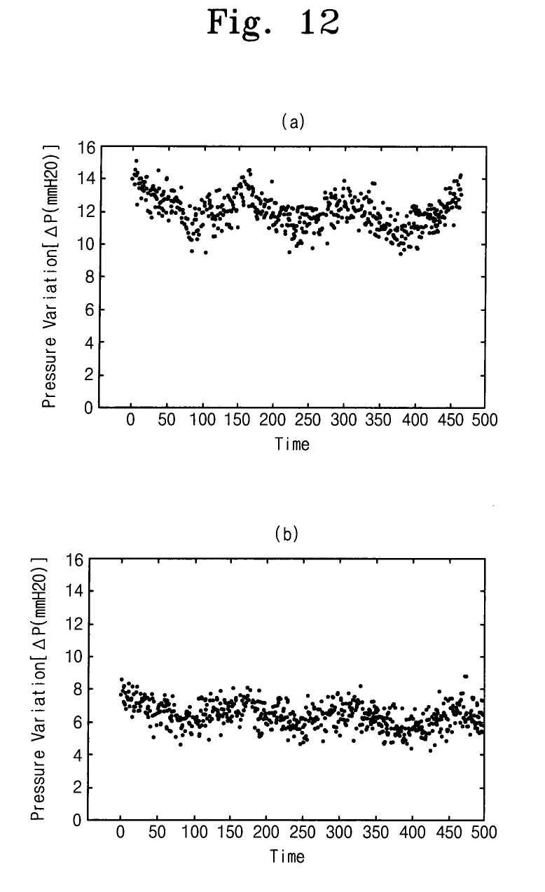

FIGS. 12(a) and (b) are graphs comparing, respectively, the fluctuation of pressure in a process chamber 30 over time when a typically configured exhaust unit is used, with the fluctuation of pressure in a process chamber 30 over time when an exhaust unit 20 according to the present embodiments is used. Referring to FIG. 12, when the exhaust unit 20 of the present embodiment is used, the change in pressure (ΔP) ranges from approximately 5 to 8 mmH2O. When the conventional exhaust is used without the regulated supplemental bypass, the change in pressure (ΔP) ranges from approximately 10 to 14 mmH2O. The invention thus provides a substantially improved reduction in pressure fluctuations.

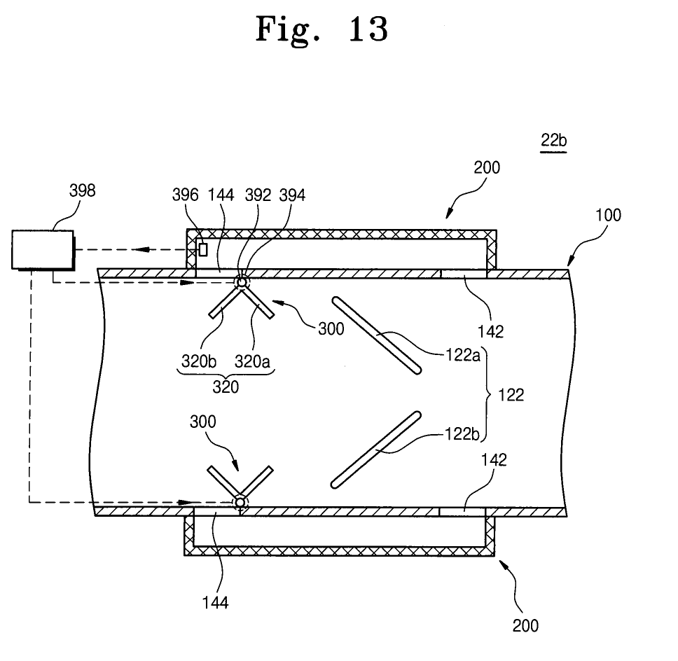

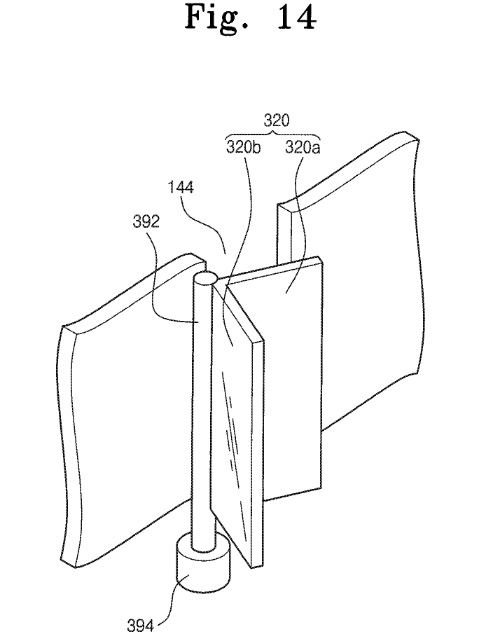

FIG. 13 is a cross-sectional view of a secondary duct 22b with regulating members 300 installed therein according to another embodiment, and FIG. 14 is a partial perspective view showing the regulating member 300 in FIG. 13. Referring to FIGS. 13 and 14, the regulating member 300 includes a flap 320, a driver 394, an airflow measurer 396, and a controller 398. While the rotation of the flap 320, being the regulating member 300, has been described in embodiments above as non-driven, the rotation of the flap 320 according to the present embodiment is achieved by being driven by the driver 394. The flap 320 used may have the same structure as the flap 320 described above, and thus, the description thereof will not be repeated. The flap 320 is fixed to a rotating shaft 392, and the rotating shaft 392 is rotatably coupled to the main exhaust duct 100. The rotating shaft 392 is coupled to a driver 394 such as a motor. The airflow measurer 396 measures the flow of gas within the supplementary exhaust duct 200. The airflow measurer 396 used may be a pressure sensor. The controller 398 receives a measured value from the airflow measurer 396, and controls the driver 394 based on the measured value. When flow of gas through the supplementary exhaust duct 200 increases, the controller 398 reduces the opening ratio of the supplementary exhaust duct 200 by rotating the flap 320 in the reducing direction, and when flow of gas through the supplementary exhaust duct 200 decreases, the controller 398 increases the opening ratio of the supplementary exhaust duct 200 by rotating the flap 320 in the increasing direction. Also, the airflow measurer 396 may measure gas flow within the main exhaust duct 100 instead of the supplementary exhaust duct 200.

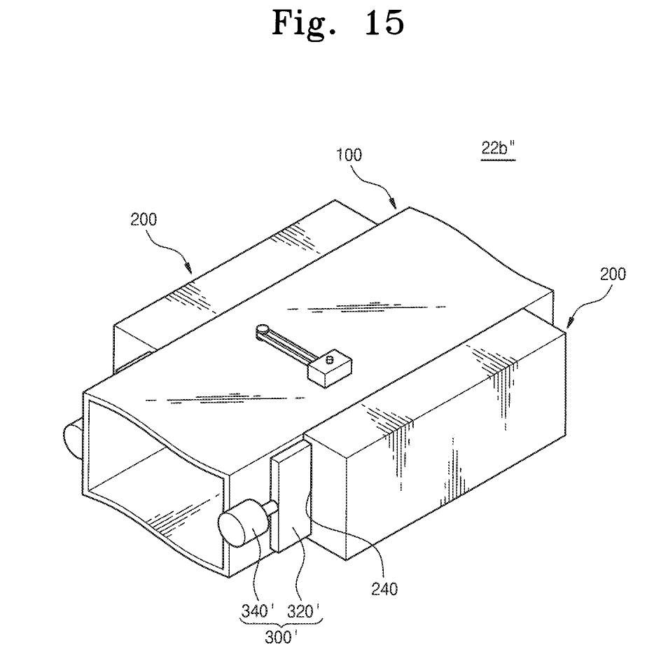

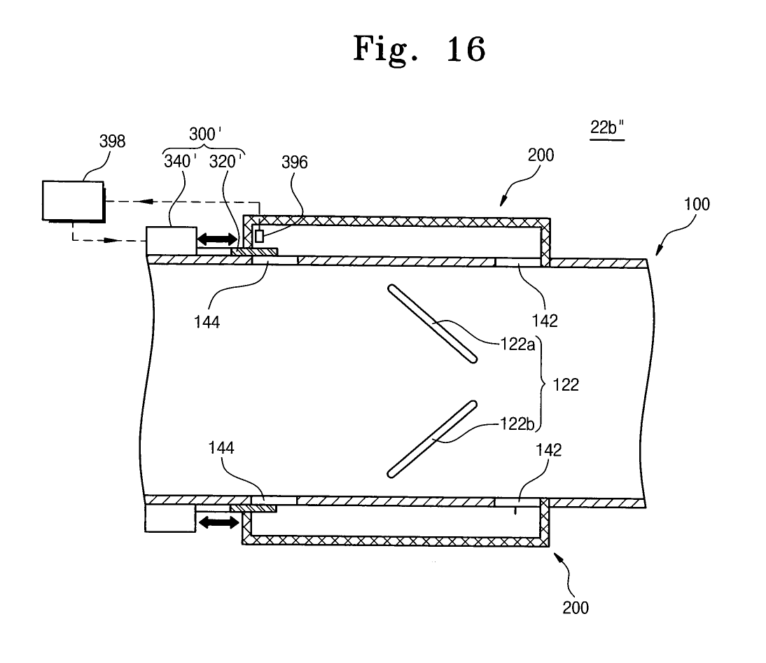

FIG. 15 and FIG. 16 are respectively a perspective and cross-sectional view of a secondary duct 22b″ with regulating members installed according to another embodiment. Referring to FIGS. 15 and 16, a regulating member 300′ regulates the opening ratio of the second opening 144 through sliding. A slit 240 is formed at the end of the sidewall of the supplementary exhaust duct 200 near the second opening 144. A plate 320′ is provided to be insertable through sliding in the slit 240. A recess (not shown) is formed in the inner wall of the supplementary exhaust duct 200 to allow an edge of the plate 320′ to insert therein and allow the plate 320′ to move smoothly by sliding. A driver 340′ moves the plate 320′ linearly, and is controlled by a controller 398 based on a received signal on a measured airflow from an airflow measurer 396.

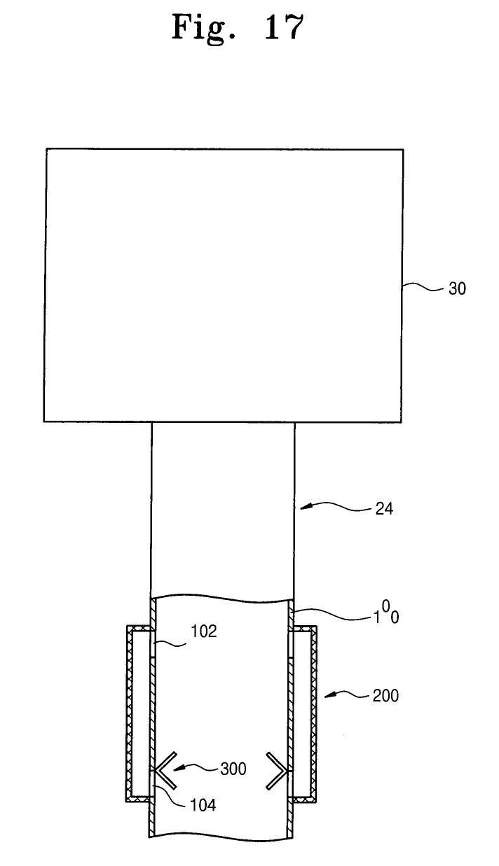

In embodiments described above, the main exhaust duct 100, the supplementary exhaust duct 200, and the regulating member 300 are installed on an integration duct 22 into which the separation ducts 24 merge. However, as shown in FIG. 17, the above-described exhaust unit 20 may be provided on each separation duct 24 connected to a respective process chamber 30. In this case, supplementary exhaust duct 200 may have a round cross-section, and the open side of the supplementary exhaust duct 200 may face the outer surface of the main exhaust duct 100. Also, a flow volume control valve (not shown) may be installed on the main exhaust duct 100 between the first opening 142 and the second opening 144 defined in the main exhaust duct 100.

According to the present embodiments, the occurrence of wide pressure fluctuations inside the process chamber due to changes in atmospheric pressure can be prevented.

Also, the structure for passively regulating the volume of exhausted gas, according to the present invention, is simple and reduces energy consumption.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An exhaust unit used to regulate pressure in a process chamber, the exhaust unit comprising:
a main exhaust duct connected to the process chamber, and including at least one of a first opening and a second opening defined in a sidewall thereof;
at least one supplementary exhaust duct with one end connected to the first opening and the other end connected to the second opening, downstream from the first opening, to allow a portion of gas flowing through the main exhaust duct to diverge from the main exhaust duct through the first opening, and re-enter the main exhaust duct through the second opening; and
a regulating member configured to regulate an opening ratio of the second opening.

2. The exhaust unit of claim 1, wherein the regulating member comprises a flap projecting into the main exhaust duct and capable of changing the opening ratio of the second opening through colliding with a volume of gas flowing through the main exhaust duct.

3. The exhaust unit of claim 2, wherein the flap is configured to decrease the opening ratio of the second opening as the volume of gas that the flap collides with in the main exhaust duct increases.

4. The exhaust unit of claim 2, wherein one end of the flap is pivotally installed near an upstream end of the second opening that is closer to the first opening, and the other end of the flap is a free end.

5. The exhaust unit of claim 2, wherein the flap comprises:
a first plate; and
a second plate extending at an angle from the first plate, with the flap pivotally connected to the exhaust unit at an intersection between the first plate and second plate.

6. The exhaust unit of claim 5, wherein the regulating member further comprises a hinge coupling an intersecting axis between the first plate and the second plate.

7. The exhaust unit of claim 5, wherein the regulating member further comprises:
bearings fixedly installed at a top and bottom end of the main exhaust duct;
a rotating shaft coupled to an intersecting axis between the first plate and second plate; and
the rotating shaft being pivotally received within the bearings thus enabling the flap to rotate smoothly.

8. The exhaust unit of claim 5, wherein the regulating member further comprises a resiliently flexible connecting member coupled between an intersecting axis between the first plate and the second plate, and to the main exhaust duct.

9. The exhaust unit of claim 2, further comprising a damper disposed within the main exhaust duct between the first opening and the second opening, to regulate the opening ratio of the main exhaust duct.

10. The exhaust unit of claim 4, wherein the supplementary exhaust duct is provided as a container with one side open and is couple to the main exhaust duct with the open side facing a side of the main exhaust duct, the supplementary exhaust having a length that enables the open side to face the first opening and the second opening at respective ends of the open side.

11. The exhaust unit of claim 2, wherein the main exhaust duct has a rectangular cross section cut across a lengthwise direction thereof, and the supplementary exhaust duct includes a pair of supplementary exhaust ducts provided respectively on opposing sidewalls of the main exhaust duct.

12. The exhaust unit of claim 2, wherein the supplementary exhaust duct is open at one side, and the open side communicates with the first and second openings.

13. The exhaust unit of claim 1, wherein the regulating member comprises:
a flap moving to regulate an opening ratio of the second opening;
a driver moving the flap;
an airflow measurer measuring a volume of gas flowing through the main exhaust duct or the supplementary exhaust duct; and
a controller controlling the driver, based on a measured value received from the airflow measurer.

14. A semiconductor manufacturing facility comprising:
a clean room;
a plurality of process chambers arranged within the clean room, to perform a semiconductor process; and
an exhaust unit regulating a pressure of the process chambers, wherein the exhaust unit includes:
an integration duct having a pressure controlling member regulating an exhaust pressure, according to a fluctuation of an atmospheric pressure; and
separation ducts diverging from the integration duct and coupled to the processing chambers, wherein the integration duct has:
a main exhaust duct with at least one of a first opening and a second opening, downstream relative to the first opening, defined in a sidewall thereof;
at least one supplementary exhaust duct with one end thereof connected to the first opening and the other end thereof connected to the second opening, to allow a portion of gas flowing through the main exhaust duct to diverge from the main exhaust duct through the first opening, and re-enter the main exhaust duct through the second opening; and
a regulating member configured to regulate an opening ratio of the second opening.

15. The semiconductor manufacturing facility of claim 14, wherein the integration duct further has:
a primary duct with the pressure controlling member installed therein; and
a secondary duct diverging from the primary duct, having the separation ducts connected thereto, and having the main exhaust duct, the supplementary exhaust duct, and the regulating member.

16. The semiconductor manufacturing facility of claim 14, wherein the exhaust unit further includes a damper disposed within the main exhaust duct between the first opening and the second opening, to adjust an opening ratio of the main exhaust duct.

17. The semiconductor manufacturing facility of claim 16, wherein the regulating member has a flap projecting into the main exhaust duct and capable of changing the opening ratio of the second opening through colliding with a volume of gas flowing through the main exhaust duct.

18. The semiconductor manufacturing facility of claim 17, wherein one end of the flap is pivotally installed near an upstream end of the second opening that is closer to the first opening, and the other end of the flap is a free end.

19. The semiconductor manufacturing facility of claim 17, wherein the flap comprises:
a first plate; and
a second plate extending at an angle from the first plate, with the flap pivotally connected to the exhaust unit at an intersection between the first plate and second plate.

20. The semiconductor manufacturing facility of claim 15, wherein the supplementary exhaust duct is coupled to the main exhaust duct at a position between a point at which the main exhaust duct diverges from the primary duct and a point at which the separation duct initially diverges from the secondary duct.

21. A method for exhausting gas from a process chamber, comprising:
simultaneously exhausting gas from within the process chamber through a main exhaust duct and a supplementary exhaust duct so that at least a portion of the gas exhausted from the process chamber is diverged from the main exhaust duct into the supplementary exhaust duct through a first opening at an upstream portion of the main exhaust and then re-enters the main exhaust duct through a second opening at a second downstream portion of the main exhaust;
changing an opening ratio of the supplementary exhaust duct according to a fluctuation of the external pressure, to reduce a range of pressure fluctuation of an internal pressure of the process chamber based on the fluctuation of the external pressure.

22. The exhausting method of claim 21, wherein the changing of the opening ratio of the supplementary exhaust duct is performed through changing an angle between the second opening and a flap rotatably installed adjacent an upstream end of the second opening.

23. The exhausting method of claim 22, wherein the flap extends into the main exhaust duct and is rotated through a change in a volume of gas colliding with the flap as the gas flows through the main exhaust duct.

24. The exhausting method of claim 23, wherein the flap comprises:
a first plate for colliding with gas flowing through the main exhaust duct; and
a second plate extending at an angle from an end of the first plate for controlling the volume of the gas flowing through the supplementary exhaust duct,
wherein the second plate is disposed between the second opening and the first plate.

25. The exhausting method of claim 21, wherein the opening ratio of the supplementary exhaust duct increases when the external pressure increases and the opening ratio of the supplementary exhaust duct decreases when the external pressure decreases.
